(19) United States
(12) Patent Application Publication
(10) Pub. No.: US 2024/0222184 A1
(43) Pub. Date: Jul. 4, 2024

(54) SEMICONDUCTOR SUBSTRATE WITH A SACRIFICIAL ANNULUS

(71) Applicant: Micron Technology, Inc., Boise, ID (US)

(72) Inventors: Jeremy E. Minnich, Boise, ID (US); Andrew M. Bayless, Boise, ID (US)

(21) Appl. No.: 18/508,239

(22) Filed: Nov. 14, 2023

Related U.S. Application Data
(60) Provisional application No. 63/435,772, filed on Dec. 28, 2022.

(51) Int. Cl. H01L 21/683; H01L 21/306; H01L 21/782; H01L 25/065

(52) U.S. Cl. CPC H01L 21/6836; H01L 21/30625; H01L 21/782; H01L 25/0657; H01L 2225/0651; H01L 2225/06513; H01L 2225/06517; H01L 2225/06586

(57) ABSTRACT

A semiconductor substrate is provided. The semiconductor substrate includes a center portion and a peripheral portion. The semiconductor substrate further includes an annulus of sacrificial material disposed at a front side of the semiconductor substrate and extending at least partially through the semiconductor substrate. The annulus of sacrificial material separates the center portion of the substrate from the peripheral portion of the substrate at the front side. The semiconductor substrate can be thinned to expose the annulus of sacrificial material and disconnect the peripheral portion from the center portion. In doing so, the thinned substrate may have a planar substrate edge void of sharp edges, thereby increasing its mechanical robustness.

### CROSS-REFERENCE TO RELATED APPLICATION(S)

The present application claims priority to U.S. Provisional Patent Application No. 63/435,772, filed Dec. 28, 2022, the disclosure of which is incorporated herein by reference in its entirety.

### TECHNICAL FIELD

The present disclosure generally relates to semiconductor device assemblies, and more particularly relates to a semiconductor substrate with a sacrificial annulus.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIGS. 1A and 1B illustrate simplified schematic cross-sectional views of a semiconductor device assembly.

FIGS. 2A through 2C illustrate simplified schematic cross-sectional views of a semiconductor device assembly in accordance with an embodiment of the present technology.

FIG. 3 illustrates a simplified schematic plan view of a semiconductor device assembly in accordance with an embodiment of the present technology.

FIGS. 4-10 illustrate simplified schematic plan and cross-sectional views of a series of steps for fabricating semiconductor device assemblies in accordance with an embodiment of the present technology.

FIG. 11 illustrates a simplified schematic cross-sectional view of a semiconductor device assembly in accordance with an embodiment of the present technology.

FIG. 12 illustrates a schematic view of a system that includes a semiconductor device assembly configured in accordance with an embodiment of the present technology.

FIG. 13 illustrates a method of fabricating a semiconductor device assembly in accordance with an embodiment of the present technology.

### DETAILED DESCRIPTION

Semiconductor devices are integrated into many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, designers continue to develop new techniques to increase the number of circuit elements on a semiconductor device without simultaneously increasing the size of the device. This development, however, may not be sustainable due to various challenges that arise from designing semiconductor devices with high circuit density. Thus, additional techniques may be required to continue the growth in capability of semiconductor devices.

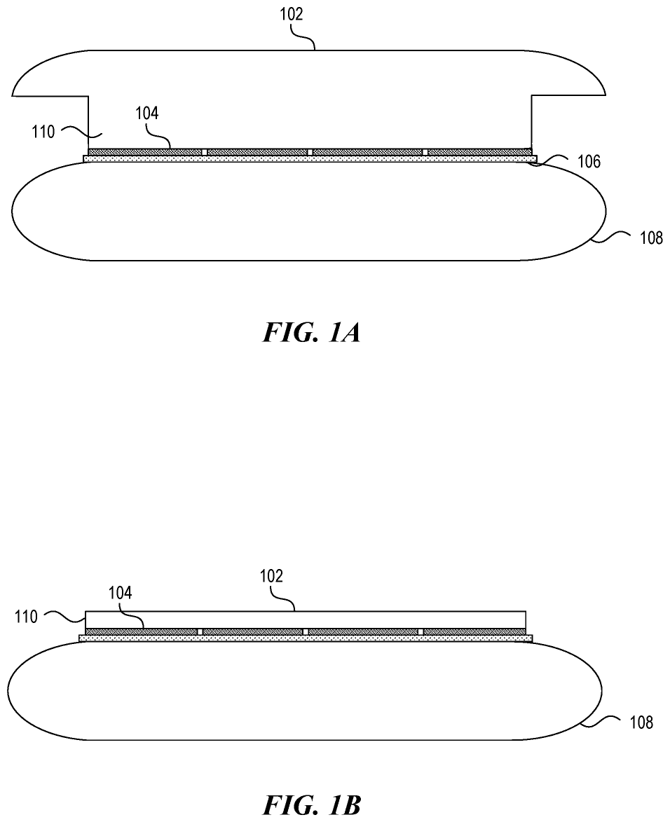

One such technique is the implementation of multiple circuit components within a single package. For example, stacked semiconductor devices enable multiple semiconductor dies to be stacked on top of one another to increase the number of circuit elements within a package without increasing its footprint. To reduce the thickness of packaged semiconductor devices, material is removed at the back side of the semiconductor dies to thin the dies. Due to curvature at the edge of the die substrate, die thinning may produce a sharp knife edge around the die. This sharp knife edge may be increasingly susceptible to cracks, which can cause failure in the semiconductor die and reduce yield. Various techniques have been developed to reduce the presence of a sharp knife edge after die thinning. One such technique is shown by way of example in FIGS. 1A and 1B.

As illustrated in FIG. 1A, a substrate 102 (e.g., semiconductor wafer) implements a plurality of semiconductor dies 104. The substrate 102 is adhered (e.g., with adhesive 106) to a carrier substrate 108 (e.g., wafer) to improve the ability of the substrate 102 to withstand processing. To reduce the presence of a sharp knife edge on the substrate 102 after die thinning, the edge 110 of the substrate 102 has been mechanically trimmed (e.g., using a saw, laser, or the like) at a front side to create a planar edge. The resulting semiconductor device assembly after back grinding the substrate 102 to thin the semiconductor dies 104 is illustrated by way of example in FIG. 1B. As illustrated, the substrate 102 has been thinned to reduce the thickness of the semiconductor dies 104. Additionally, given that the edge 110 at the front side of the substrate 102 was trimmed to form a planar edge, a sharp knife edge is not present after die thinning. Instead, the edge 110 is a planar surface extending between the front side and the back side of the substrate 102.

While the mechanical edge trimming of the edge 110 may reduce the presence of a sharp knife edge after die trimming, trimming the edge 110 of the substrate 102 may cause particulates from the substrate 102 to fall onto the front side of the semiconductor dies 104 at which circuitry is disposed. Many of these particulates may be difficult to remove even with scanning electron microscope (SEM) level cleaning. Thus, these particulates may remain at the front side of the semiconductor dies 104 even after packaging. In some cases, these particulates may cause failures in operation of the semiconductor dies 104. Moreover, particulates at the front side of the semiconductor dies 104 may limit the robustness of connections formed thereat, for example, interconnects between semiconductor dies in a stacked die package. Accordingly, utilizing mechanical edge trimming to limit the presence of sharp knife edges on a die substrate may inhibit the performance of the semiconductor dies.

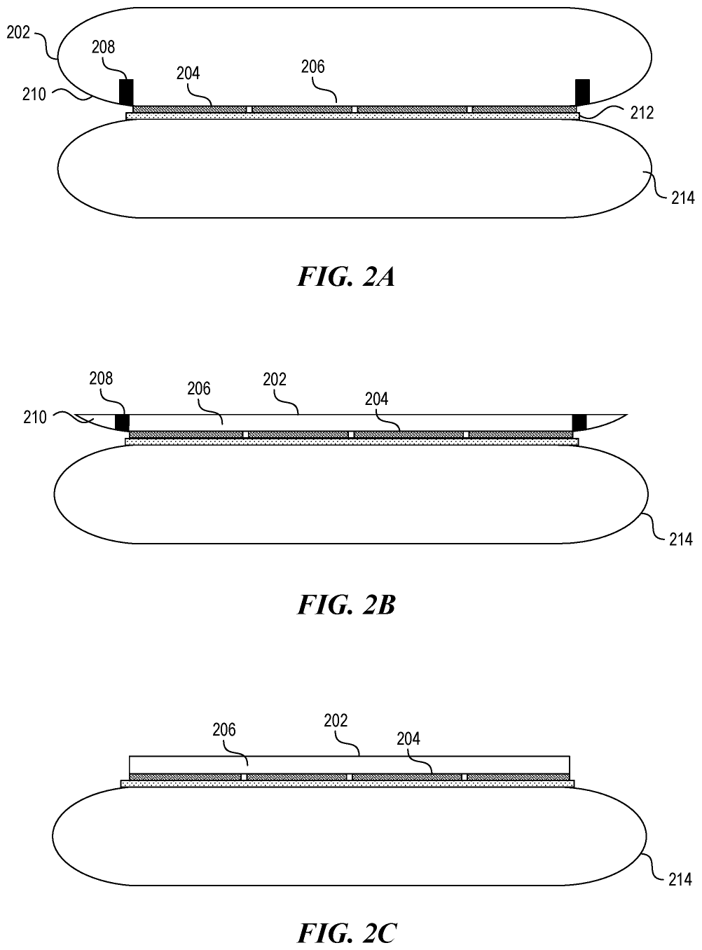

To address these drawbacks and others, various embodiments of the present application provide semiconductor device assemblies that implement a semiconductor substrate with an annulus of sacrificial material. The semiconductor substrate includes a center portion and a peripheral portion. The annulus of sacrificial material is disposed at a front side of the semiconductor substrate, and it extends at least partially through the semiconductor substrate. The annulus of sacrificial material separates the center portion of the substrate from the peripheral portion of the substrate at the front side. The semiconductor substrate can be thinned to expose the annulus of sacrificial material and disconnect the peripheral portion from the center portion. In doing so, the thinned substrate may have a planar substrate edge void of sharp edges, thereby increasing its mechanical robustness. An example semiconductor device assembly is shown in FIGS. 2A through 2C.

FIG. 2A illustrates a semiconductor device assembly that includes a semiconductor substrate 202 (e.g., semiconductor wafer). Circuitry is disposed at the front side of the substrate 202 to implement one or more semiconductor dies 204. The semiconductor dies 204 may be implemented at a center portion 206 of the substrate 202. An annulus of sacrificial material 208 may be disposed at the front side of the substrate 202 and extend at least partially into the substrate 202. The annulus of sacrificial material 208 may separate the center portion 206 and a peripheral portion 210 of the substrate 202 at the front side. The annulus of sacrificial material 208 may include any temporary material that can later be removed. For example, the temporary material can be an adhesive, a dielectric material (e.g., silicon oxide, silicon nitride, silicon carbide, silicon carbon nitride, etc.), a resin (e.g., water-soluble resin, HogoMax®, etc.), or the like. In some cases, the annulus of sacrificial material 208 may be soluble to a solvent to enable the annulus of sacrificial material 208 to be removed by exposing it to the solvent.

Once the circuitry and the annulus of sacrificial material 208 have been disposed on the substrate 202, the substrate 202 may be adhered (e.g., through an adhesive 212) to a carrier substrate 214 (e.g., wafer) to support the semiconductor dies 204 during processing. The substrate 202 may be adhered to the carrier substrate 214 in a face-down position such that the front side of the substrate 202 at which circuitry is disposed is adhered to the carrier substrate 214 and a back side of the substrate 202 is exposed. In this way, the substrate 202 may be thinned at the back side. The resulting semiconductor device assembly is shown by way of example in FIG. 2B.

As illustrated in FIG. 2B, the substrate 202 may be thinned at the back side to expose the annulus of sacrificial material 208 at the back side of the substrate 202. The substrate 202 may be thinned such that the thickness of the semiconductor dies 204 satisfies spatial requirements. For example, the substrate 202 may be thinned such that the total thickness of the semiconductor dies 204 is less than 25 microns, 30 microns, 35 microns, 40 microns, 50 microns, 75 microns, 100 microns, or the like. By thinning the substrate 202, a portion of the substrate 202 connecting the center portion 206 of the substrate 202 and the peripheral portion 210 of the substrate 202 may be removed. In this way, the center portion 206 may be separated from the peripheral portion 210 by the annulus of sacrificial material 208. As such, cracks caused due to the sharp knife edge at the peripheral portion 210 may not propagate through the annulus of sacrificial material 208 to the center portion 206. As a result, the semiconductor dies 204 may be less susceptible to failure. After thinning the substrate 202 to expose the annulus of sacrificial material 208 at the back side of the substrate 202, the annulus of sacrificial material 208 is removed, as shown by way of example in FIG. 2C.

As illustrated in FIG. 2C, the annulus of sacrificial material 208 is removed from the substrate 202. The annulus of sacrificial material 208 may be removed through any appropriate method (e.g., dissolving, etching, etc.). In aspects, the annulus of sacrificial material 208 may be dissolved using a solvent that the sacrificial material is soluble to. In some cases, the annulus of sacrificial material 208 may be removed in conjunction with planarizing the back surface of the substrate 202 (e.g., in a same process step). For example, the back surface of the substrate may undergo chemical-mechanical planarization (CMP), and the annulus of sacrificial material 208 may be soluble to a solvent or slurry used during CMP. In this way, the annulus of sacrificial material 208 may be removed without adding process steps to fabrication.

Given that the annulus of sacrificial material 208 separates the center portion 206 and the peripheral portion 210 of the substrate 202, removing the annulus of sacrificial material 208 may disconnect the peripheral portion 210 of the substrate 202 from the center portion 206 of the substrate 202. Given that, in the illustrated example, the center portion 206 is adhered to the carrier substrate 214 and the peripheral portion 210 is not, the peripheral portion 210 may be removed from the semiconductor device assembly when the annulus of sacrificial material 208 is removed. As illustrated in FIGS. 2A and 2B, the center portion 206 of the substrate 202 and the annulus of sacrificial material 208 may make contact at a planar edge extending from the front side of the substrate 202 toward the back side of the substrate 202. Thus, when the annulus of sacrificial material 208 is removed, the substrate 202 may be left with a planar edge extending between the front side and the back side that is void of sharp knife edges. In this way, the substrate 202 may be less susceptible to cracking and yield may increase.

In contrast to the semiconductor device assembly illustrated in FIGS. 1A and 1B, the semiconductor device assembly illustrated in FIGS. 2A through 2C may be fabricated without mechanical edge trimming. Instead, the occurrence of sharp knife edges surrounding the substrate 202 may be mitigated through the annulus of sacrificial material 208. In this way, the resulting semiconductor dies 204 implemented at the substrate 202 may not include the particulates formed as a result of mechanically trimming the edge of the substrate. As a result, the front side of the wafer at which the circuitry for the semiconductor dies 204 is disposed may include fewer particulates than found in semiconductor dies fabricated using mechanical edge trimming. For example, the semiconductor dies 204 may include a rate of particulates fewer than 25 particulates of a size less than 90 microns per wafer (e.g., 70,650 millimeters squared area), fewer than 30 particulates of a size less than 90 microns per wafer, fewer than 35 particulates of a size less than 90 microns per wafer, or fewer than 40 particulates of a size less than 90 microns per wafer. Moreover, SEM-level cleaning may not be needed to clean the front side of the semiconductor dies 204.

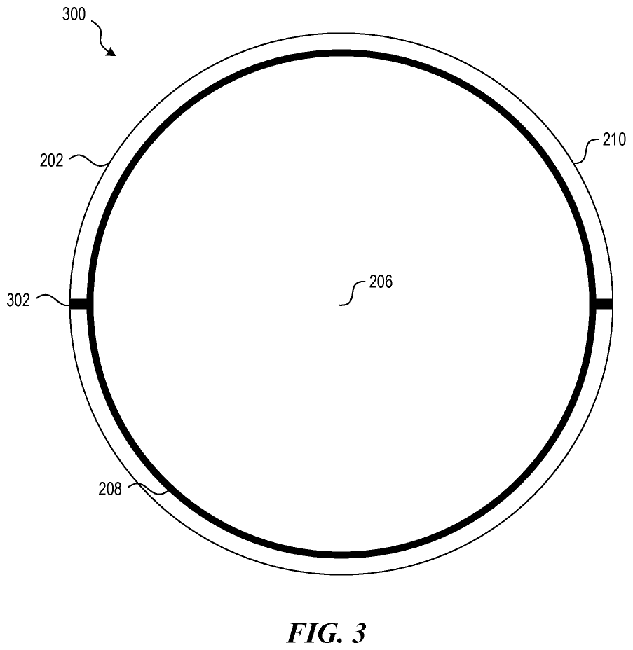

FIG. 3 illustrates a simplified schematic plan view of an example semiconductor device assembly 300 in accordance with an embodiment of the present technology. The semiconductor device assembly 300 may include a substrate 202 with an annulus of sacrificial material 208. The view shown in FIG. 3 may correspond to a view of the front side of the semiconductor substrate 202 at which the annulus of sacrificial material 208 is disposed. The annulus of sacrificial material 208 may be a circular annulus, rectangular annulus, or any other shape of annulus. The annulus of sacrificial material 208 may be disposed a distance from the periphery of the substrate 202. The annulus of sacrificial material 208 may separate the center portion 206 of the substrate 202 and the peripheral portion 210 of the substrate 202 at the front side.

In some implementations, the annulus of sacrificial material 208 may extend only partially through the substrate 202. For example, the annulus of sacrificial material 208 may extend far enough into the substrate such that it is exposed when the substrate 202 is thinned at the back side (e.g., the annulus of sacrificial material may extend less than 25 microns, 30 microns, 35 microns, 40 microns, 50 microns, 75 microns, 100 microns, or the like). In other implementations, the annulus of sacrificial material 208 may extend entirely through the substrate 202 to the back side. The annulus of sacrificial material 208 or the two or more portions of sacrificial material 302 may have any thickness. The annulus of sacrificial material 208 or the two or more portions of sacrificial material 302 may have a thickness based on the depth to which the sacrificial material is deposited. For example, the sacrificial material may be deposited with an aspect ratio of 2, 5, 10, 15, or the like. Accordingly, the thickness of the annulus of sacrificial material 208 or the two or more portions of sacrificial material 302 may have a thickness of less than 2 microns, less than 5 microns, less than 10 microns, less than 20 microns, less than 25 microns, or the like.

In aspects, the substrate 202 may include two or more portions of sacrificial material 302 that extend from the annulus of sacrificial material 208 to the periphery of the substrate 202. The two or more portions of sacrificial material 302 may be disposed at the front side of the substrate 202 to a same or different depth than the annulus of sacrificial material 208. The two or more portions of sacrificial material 302 may include a sacrificial material that is the same as or different from the annulus of sacrificial material 208. The two or more portions of sacrificial material 302 may partition the peripheral portion 210 at the front side. In some implementations, the two or more portions of sacrificial material 302 may be distributed equally about the periphery of the substrate 202 to create equally sized partitions. For example, as illustrated, the two or more portions of sacrificial material 302 are placed at opposite sides of the substrate 202 to divide the peripheral portion 210 into two equally sized partitions. In other implementations, any number of portions (e.g., three, four, five, ten, or the like) of sacrificial material may be disposed at the front surface of the substrate 202.

When the substrate 202 is thinned, the two or more portions of sacrificial material 208 may be exposed at the back side of the substrate 202. In this way, the two or more portions of sacrificial material 208 may be removed through any of the techniques discussed with respect to the annulus of sacrificial material 208. In some cases, the two or more portions of sacrificial material 302 may be removed in conjunction with removing the annulus of sacrificial material 208. Given that the two or more portions of sacrificial material 302 may partition the peripheral portion 210, removing the two or more portions of sacrificial material 302 may disconnect the partitions of the peripheral portion 210 from one another. As a result, the various partitions of the peripheral portion 210 may be disconnected from the center portion 206 of the substrate 202 and removed individually.

As used herein, the annulus of sacrificial material may refer to the annulus of sacrificial material 208 alone or to the annulus of sacrificial material 208 and the two or more portions of sacrificial material 302 in combination. Thus, although described separately with respect to FIG. 3, the annulus of sacrificial material 208 and the two or more portions of sacrificial material 302 may be a single continuous structure referred to as the annulus of sacrificial material.

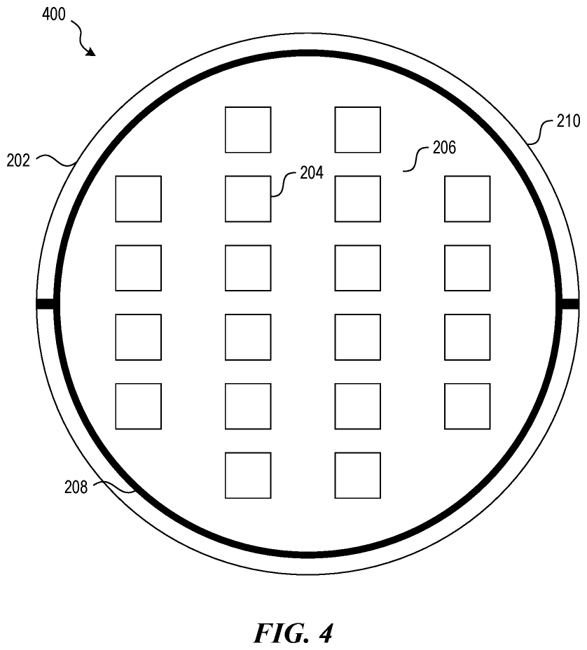

This disclosure now turns to a series of steps for fabricating semiconductor device assemblies in accordance with an embodiment of the present technology. Specifically, FIGS. 4-10 illustrate simplified schematic plan and cross-sectional views of a series of steps for fabricating semiconductor device assemblies in accordance with an embodiment of the present technology. In some embodiments, the fabrication may be performed at the wafer level, panel level, strip level, package level, or die level. Thus, in some embodiments, multiple semiconductor devices may be fabricated on a single substrate, and the multiple devices may be separated from one another during fabrication. In other embodiments, the substrates may be pre-singulated substrates, and a single semiconductor device may be fabricated on the substrate.

Beginning with FIG. 4 at stage 400, a substrate 202 is provided. The view shown in FIG. 4 may correspond to a front side view of the substrate 202. The substrate 202 includes an annulus of sacrificial material 208 disposed at the front side. The annulus of sacrificial material 208 may separate the center portion 206 of the substrate 202 and the peripheral portion 210 of the substrate 202 at the front side. The annulus of sacrificial material 208 may be disposed at the front side of the substrate 202 through any appropriate method. For example, material may be removed from the front side of the substrate 202 to create an opening that corresponds to the annulus of sacrificial material 208, and sacrificial material may be disposed in the opening to implement the annulus of sacrificial material 208. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, CMP, or other suitable techniques.

The substrate 202 may further include circuitry to implement one or more semiconductor dies 204 at the substrate 202 (e.g., at the center portion 206). The circuitry may be disposed on the substrate 202 through one or more steps of removing and depositing material. Materials can be deposited and removed through any of the processes discussed above with respect to the annulus of sacrificial material 208. In some implementations, the annulus of sacrificial material 208 and the circuitry may be disposed at the substrate 202 in conjunction with one another (e.g., in a same process step). In this way, creating the annulus of sacrificial material 208 may not add process steps to semiconductor device fabrication. As illustrated, the annulus of sacrificial material 208 may surround the semiconductor dies 204 at the center portion 206 of the substrate 202.

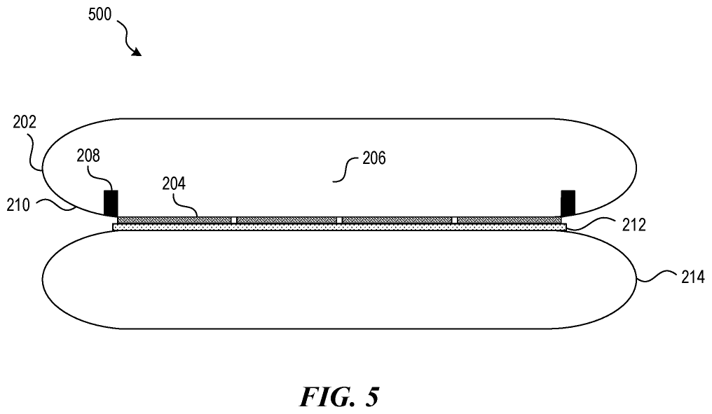

Turning to FIG. 5 at stage 500, the substrate 202 is adhered (e.g., through an adhesive 212) to a carrier substrate 214. The substrate 202 may be assembled onto the carrier substrate 214 such that the front side is adhered to the carrier substrate 214 and the back side is exposed. The substrate 202 may be adhered to the carrier substrate 214 only at the center portion 206 at which the semiconductor dies 204 are implemented. In this way, the peripheral portion 210 may not be adhered directly to the carrier substrate 214.

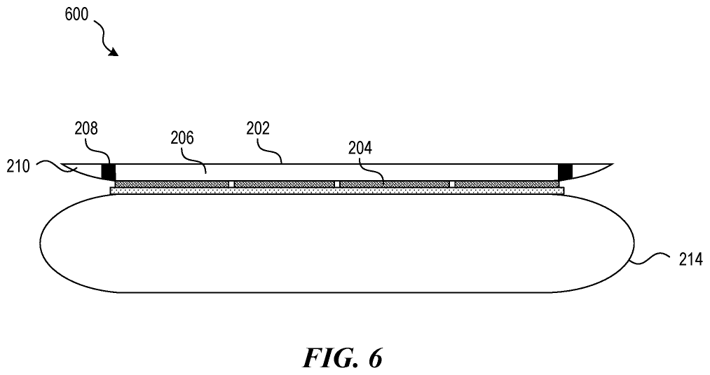

Turning next to FIG. 6 at stage 600, the substrate 202 is thinned at the back side to expose the annulus of sacrificial material 208 at the back side. The substrate 202 may be thinned through any appropriate technique to implement thinned semiconductor dies 204 that satisfy the spatial constraints associated with being packaged into a semiconductor device. For example, the substrate 202 may be thinned through back grinding or CMP. After the substrate 202 is thinned, the annulus of sacrificial material 208 may separate the peripheral portion 210 of the substrate 202 and the center portion 206 of the substrate 202. Moreover, the peripheral portion 210 may only be connected with the center portion 206 through the annulus of sacrificial material 208.

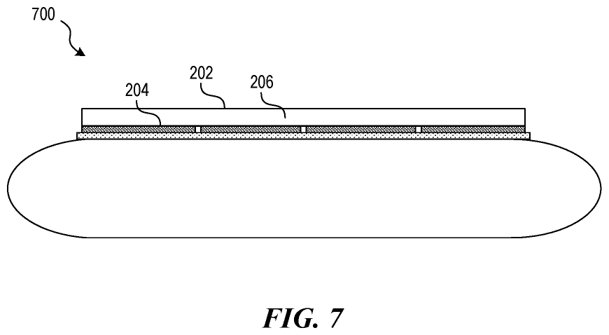

Turning next to FIG. 7 at stage 700, the annulus of sacrificial material 208 may be removed to disconnect the peripheral portion of the substrate 202. The annulus of sacrificial material 208 may be removed through any appropriate technique. In some implementations, the annulus of sacrificial material 208 may be removed through etching. In some implementations, the annulus of sacrificial material 208 may be removed by applying a solvent to the annulus of sacrificial material 208 (e.g., at the back surface of the substrate 202) to dissolve the sacrificial material. In some cases, the annulus of sacrificial material 208 may be soluble to a solvent or slurry used for CMP. In these implementations, the annulus of sacrificial material 208 may be removed in conjunction with planarizing the back side of the substrate 202. As a result of removing the annulus of sacrificial material 208, the peripheral portion of the substrate 202 may be removed from the center portion 206 of the substrate 202. The resulting edge extending between the front side and the back side of the substrate 202 may have a planar surface that is less susceptible to cracking in comparison to a substrate having a sharp knife edge.

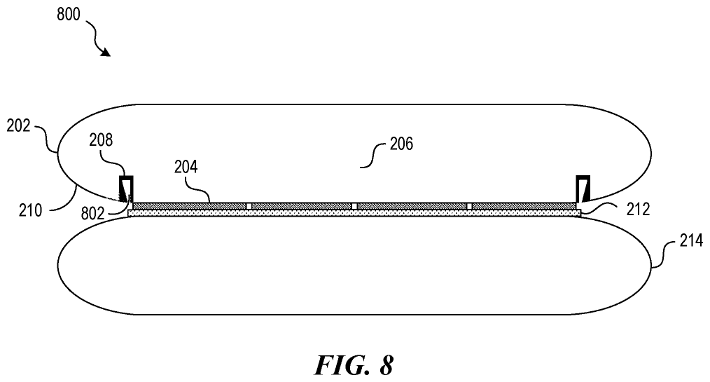

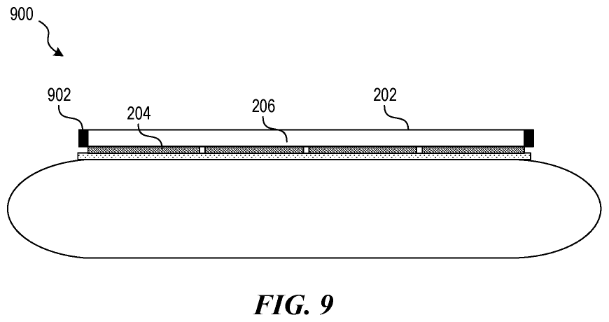

While the steps illustrated in FIGS. 5 through 7 may be implemented to fabricate a semiconductor device assembly void of sharp knife edges, other techniques may be used in addition to or as an alternative to these steps. For example, FIGS. 8 and 9 illustrate steps for fabricating a semiconductor device assembly by implementing an annulus of sacrificial material that includes a vacancy. Specifically, FIG. 8 at stage 800 illustrates a substrate 202 that includes an annulus of sacrificial material 208 separating a center portion 206 and a peripheral portion 210 at the front side. Circuitry is disposed at the center portion 206 to implement semiconductor dies 204. The substrate 202 is adhered to the carrier substrate 214 through an adhesive 212. Unlike the example illustrated in FIGS. 5 through 7, the annulus of sacrificial material 208 illustrated in FIG. 8 includes a vacancy 802. The vacancy 802 may extend through the annulus of sacrificial material 208 such that the sacrificial material does not entirely fill the opening created in the substrate 202. The vacancy 802 may be created within the annulus of sacrificial material 208 by pinching off the sacrificial material to leave the vacancy 802. In some implementations, the annulus of sacrificial material 208 may be disposed on the surfaces of the opening created in the substrate 202 while leaving the center of the opening vacant. The different portions of the annulus of sacrificial material 208 may be connected at a side closest to the back side of the substrate 202.

Turning next to FIG. 9 at stage 900, the substrate 202 may be thinned at the back side to expose the vacancy. Given that the substrate 202 is thinned to expose the vacancy, the portion of the annulus of sacrificial material that connects to the sacrificial material at each of the surfaces of the opening may be removed. In this way, the peripheral portion of the substrate may be disconnected from the center portion without having to completely remove the sacrificial material. Instead, a portion of the sacrificial material 902 that was disposed on the edge of the center portion 206 of the substrate 202 may remain. In doing so, the portion of the sacrificial material 902 may protect the substrate 202 from damage at the edge. In contrast to entirely removing the annulus of sacrificial material, as shown in FIG. 7, the peripheral portion of the substrate 202 may be removed solely by thinning the back side of the substrate 202 to the vacancy. The portion of the sacrificial material 902 remaining at the edge of the substrate 202 may not be removed until the semiconductor dies 204 are diced. In this way, a sacrificial material removal step may not be needed. In other implementations, the portion of the sacrificial material 902 may be removed similar to the removal of sacrificial material described with respect to FIG. 7.

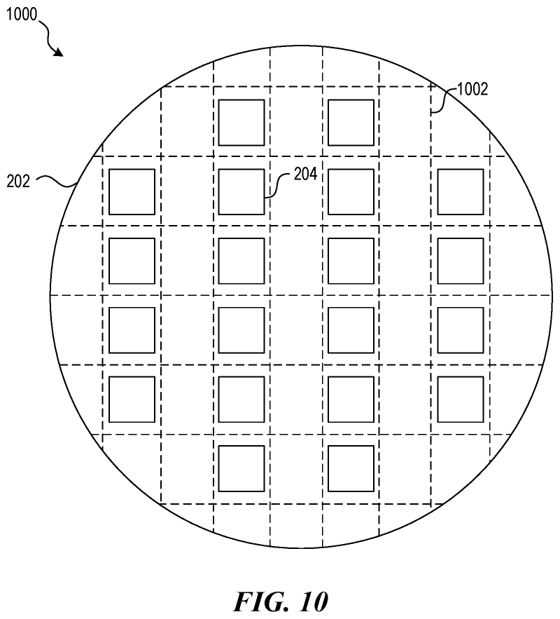

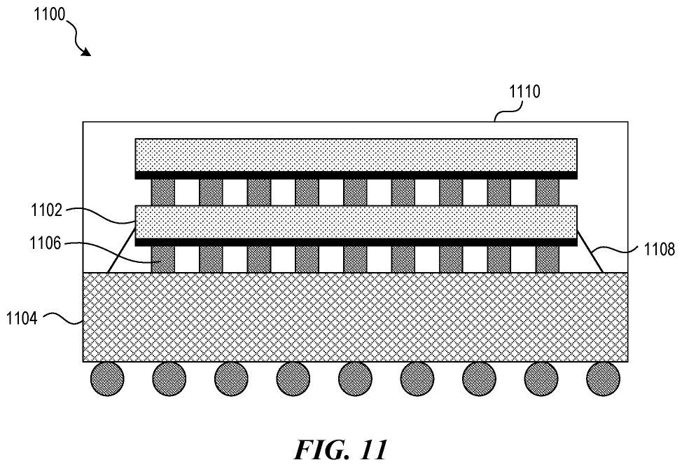

Turning next to FIG. 10 at stage 1000, the substrate 202 may be diced along dice lines 1002 to singulate the semiconductor dies 204. The semiconductor dies 204 may be diced through any appropriate technique. In some cases, the substrate 202 includes a portion of the sacrificial material (e.g., a portion of the sacrificial material 902 of FIG. 9). In these examples, the portion of the sacrificial material may be removed or the substrate 202 may be diced with the sacrificial material still attached to the edge of the substrate 202, thereby separating the portion of sacrificial material from the semiconductor dies 204. The singulated dies may then be packaged into one or more semiconductor devices, for example, as shown in FIG. 11.

FIG. 11 illustrates a simplified schematic cross-sectional view of a semiconductor device assembly 1100 in accordance with an embodiment of the present technology. As can be seen with reference to FIG. 11, the semiconductor device assembly 1100 can include semiconductor dies 1102 assembled onto a package-level substrate 1104 (e.g., in a flip-chip arrangement). The semiconductor dies 1102 may be fabricated on a semiconductor substrate that includes an annulus of sacrificial material. In aspects, the semiconductor dies 1102 may be fabricated without mechanically trimming the edge of the substrate at the front side. In doing so, particulates from mechanically trimming the edge of the substrate may not be present on the semiconductor dies 1102. For example, the semiconductor dies 1102 fabricated from a semiconductor substrate may include a rate of particulates fewer than 25 particulates of a size less than 90 microns per wafer (e.g., 70,650 millimeters squared area), fewer than 30 particulates of a size less than 90 microns per wafer, fewer than 35 particulates of a size less than 90 microns per wafer, or fewer than 40 particulates of a size less than 90 microns per wafer.

Interconnects 1106 may be formed between contact pads at the semiconductor dies 1102 and contact pads at the substrate 1104 to enable electrical signals to pass between the semiconductor dies 1102 and the substrate 1104. The semiconductor dies 1102 may include traces, lines, vias, or other electrical connection structures that connect circuitry at the semiconductor dies 1102 to the contact pads. As illustrated, multiple semiconductor dies 1102 may be stacked in a single package, and interconnects 1106 may be formed between the stacked semiconductor dies 1102. The semiconductor dies 1102 may include one or more through-silicon vias (TSVs) to enable electrical signals to be passed between the stacked semiconductor dies 1102 exclusive of the substrate 1104 or other circuitry.

The substrate 1104 can further include package-level contact pads that provide external connectivity (e.g., via solder balls) to the semiconductor dies 1102 (e.g., power, ground, and I/O signals) through traces, lines, vias, and other electrical connection structures in the substrate 1104 that electrically connect the package-level contact pads to contact pads at an upper surface of the substrate 1104. An underfill material 1108 (e.g., capillary underfill) can be provided between the semiconductor dies 1102 and the substrate 1104 to provide electrical insulation to the interconnects 1106 and structurally support the semiconductor dies 1102. The assembly 1100 can further include an encapsulant material 1110 (e.g., mold resin compound or the like) that at least partially encapsulates the semiconductor dies 1102 and the substrate 1104 to prevent electrical contact therewith and provide mechanical strength and protection to the assembly.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with, e.g., a vertical stack of semiconductor dies, a plurality of semiconductor dies, a single semiconductor die, mutatis mutandis.

In accordance with one aspect of the present disclosure, the semiconductor devices illustrated in the assemblies of FIGS. 1-11 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

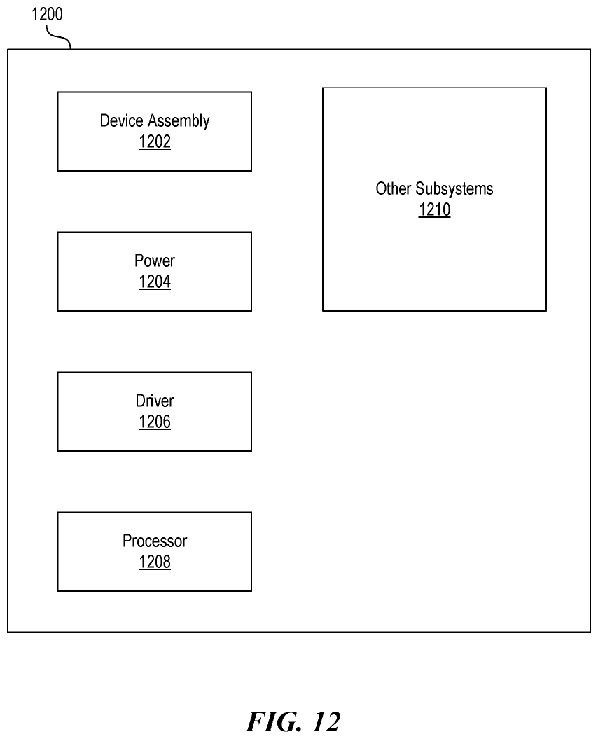

Any one of the semiconductor devices and semiconductor device assemblies described above with reference to FIGS. 1-11 can be incorporated into any of a myriad of larger and/or more complex systems, a representative example of which is system 1200 shown schematically in FIG. 12. The system 1200 can include a semiconductor device assembly 1202 (e.g., or a discrete semiconductor device), a power source 1204, a driver 1206, a processor 1208, and/or other subsystems or components 1210. The semiconductor device assembly 1202 can include features generally similar to those of the semiconductor device assemblies described above with reference to FIGS. 1-11. The resulting system 1200 can perform any of a wide variety of functions, such as memory storage, data processing, and/or other suitable functions. Accordingly, representative systems 1200 can include, without limitation, hand-held devices (e.g., mobile phones, tablets, digital readers, and digital audio players), computers, vehicles, appliances, and other products. Components of the system 1200 may be housed in a single unit or distributed over multiple, interconnected units (e.g., through a communications network). The components of the system 1200 can also include remote devices and any of a wide variety of computer-readable media.

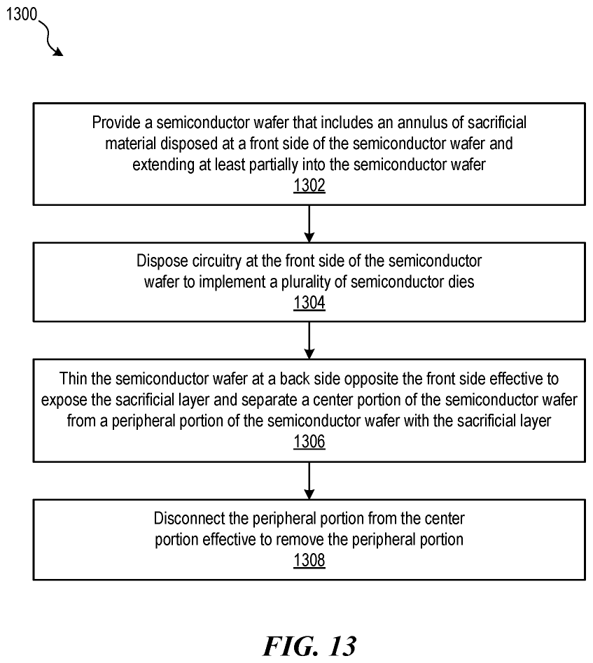

FIG. 13 illustrates an example method 1300 for fabricating a semiconductor device assembly in accordance with an embodiment of the present technology. The method 1300 may, for illustrative purposes, be described with respect to features, components, or elements of FIGS. 1-12. Although illustrated in a particular configuration, one or more operations of the method 1300 may be omitted, repeated, or reorganized. Additionally, the method 1300 may include other operations not illustrated in FIG. 13, for example, operations detailed in one or more other methods described herein.

At 1302, a semiconductor substrate 202 (e.g., wafer) is provided that includes an annulus of sacrificial material 208 disposed at a front side of the semiconductor substrate 202 and extending at least partially into the semiconductor substrate 202. In some implementations, the annulus of sacrificial material 208 may be pinched off such that a vacancy 802 extends through the annulus of sacrificial material 208. The annulus of sacrificial material 208 may be implemented by removing (e.g., etching) material from the front side of the substrate 202 to create an opening and disposing sacrificial material at the opening. At 1304, circuitry is disposed at the front side of the semiconductor substrate 202 to implement a plurality of semiconductor dies 204. In some implementations, the circuitry may be disposed in conjunction with disposing the annulus of sacrificial material 208 at the front side. In doing so, the annulus of sacrificial material 208 may be created without additional processing steps to fabricate a semiconductor device.

At 1306, the semiconductor substrate 202 is thinned at a back side opposite the front side effective to expose the annulus of sacrificial material 208 and separate a center portion 206 of the semiconductor substrate 202 from a peripheral portion 210 of the semiconductor substrate 202 with the annulus of sacrificial material 208. At 1308, the peripheral portion 210 is disconnected from the center portion 206 effective to remove the peripheral portion 210. In some implementations, removing the peripheral portion may include dissolving the annulus of sacrificial material 208 that separates the center portion 206 and the peripheral portion 210 using a solvent. In aspects, the solvent may include a solvent or slurry used for CMP and dissolving the annulus of sacrificial material 208 may be performed in conjunction with planarizing the back side of the substrate 202 (e.g., using CMP). In some implementations, the annulus of sacrificial material 208 includes a vacancy 802 and disconnecting the peripheral portion 210 from the center portion 206 effective to remove the peripheral portion 210 includes thinning the semiconductor substrate 202 at the back side to the vacancy 802 such that a portion of the sacrificial material 902 remains at an edge of the center portion 206 of the substrate 202. In some cases, dicing the plurality of semiconductor dies 204 is effective to remove the portion of the sacrificial material 902 from the plurality of semiconductor dies 204. In aspects, the method 1300 may limit the occurrence of sharp knife edges on a substrate 202 without mechanically trimming the edge of the substrate 202 at the front side.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a printed circuit board (PCB) or wafer-level substrate, a die-level substrate, or another die for die-stacking or three-dimensional interconnect (3DI) applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A method for fabricating a semiconductor device assembly, comprising:
providing a semiconductor wafer that includes an annulus of sacrificial material disposed at a front side of the semiconductor wafer and extending at least partially into the semiconductor wafer;
disposing circuitry at the front side of the semiconductor wafer to implement a plurality of semiconductor dies;
thinning the semiconductor wafer at a back side opposite the front side effective to expose the annulus of sacrificial material and remove a portion of the semiconductor wafer that connects a center portion of the semiconductor wafer to a peripheral portion of the semiconductor wafer; and
disconnecting the peripheral portion from the center portion effective to remove the peripheral portion from the semiconductor wafer.

2. The method of claim 1, wherein disconnecting the peripheral portion from the center portion effective to remove the peripheral portion from the semiconductor wafer includes dissolving the annulus of sacrificial material using a solvent.

3. The method of claim 2, wherein:
the solvent is a solvent or slurry used for chemical-mechanical planarization; and
dissolving the annulus of sacrificial material is performed in conjunction with planarizing the back side of the semiconductor wafer using chemical-mechanical planarization.

4. The method of claim 1, wherein:
the annulus of sacrificial material is pinched off at the front side such that a vacancy extends through the annulus of sacrificial material; and
disconnecting the peripheral portion from the center portion effective to remove the peripheral portion includes thinning the semiconductor wafer at the back side to the vacancy such that a portion of the annulus of sacrificial material remains at an edge of the center portion.

5. The method of claim 4, further comprising dicing the plurality of semiconductor dies effective to remove the portion of the annulus of sacrificial material from the plurality of semiconductor dies.

6. The method of claim 1, wherein the method does not include mechanically trimming an edge of the semiconductor wafer at the front side.

7. The method of claim 1, wherein providing the semiconductor wafer that includes the annulus of sacrificial material includes:
etching the semiconductor wafer at the front side to create an opening; and
disposing sacrificial material in the opening to create the annulus of sacrificial material.

8. The method of claim 7, wherein etching the semiconductor wafer at the front side or disposing the sacrificial material in the opening is performed in conjunction with disposing circuitry at the front side.

9. The method of claim 1, wherein disconnecting the peripheral portion from the center portion includes separating the peripheral portion into a plurality of pieces.

10. A semiconductor wafer, comprising:
a front side;
a center portion;
a peripheral portion; and
an annulus of sacrificial material disposed at the front side, extending partially through the semiconductor wafer, and separating the center portion from the peripheral portion at the front side.

11. The semiconductor wafer of claim 10, further comprising two or more portions of sacrificial material disposed at the front side, the two or more portions of sacrificial material extending from the annulus of sacrificial material to a periphery of the semiconductor wafer.

12. The semiconductor wafer of claim 11, wherein the two or more portions of sacrificial material partition the peripheral portion into equally sized portions.

13. The semiconductor wafer of claim 10, wherein the annulus of sacrificial material is soluble to a solvent.

14. The semiconductor wafer of claim 13, wherein the solvent is a solvent or slurry used during chemical-mechanical planarization.

15. The semiconductor wafer of claim 10, wherein the annulus of sacrificial material is pinched off at the front side such that a vacancy extends through the annulus of sacrificial material.

16. The semiconductor wafer of claim 10, wherein the annulus of sacrificial material is a circular annulus of sacrificial material.

17. The semiconductor wafer of claim 10, wherein the annulus of sacrificial material includes an adhesive.

18. The semiconductor wafer of claim 10, wherein the annulus of sacrificial material includes a dielectric material.

19. The semiconductor wafer of claim 10, wherein the annulus of sacrificial material includes a water-soluble resin.

20. A semiconductor device assembly, comprising:
a plurality of semiconductor dies singulated from a semiconductor wafer, the plurality of semiconductor dies having:
a front side at which circuitry is disposed; and
a back side opposite the front side,
wherein the front side of the plurality of semiconductor dies has a rate of particulates fewer than 30 particles of a size less than 90 microns per 70,650 millimeters squared area.
